(19) United States
(12) Patent Application Publication
(10) Pub. No.: US 2013/0008250 A1
(43) Pub. Date: Jan. 10, 2013

(54) Substrate material having a mechanical filtering characteristic and method for producing a substrate material

(76) Inventors: Mariusz Koc, Stuttgart (DE); Ralf Schober, Marbach (DE)

(21) Appl. No.: 13/521,904

(22) PCT Filed: Dec. 6, 2010
(86) PCT No.: PCT/EP2010/068943

§ 371 Date: Sep. 27, 2012

(30) Foreign Application Priority Data
Jan. 13, 2010 (DE) 102010000848.6

(51) Int. Cl. G01D 11/10; H05K 13/00; H05K 7/00; G01P 1/02

(52) U.S. Cl. 73/493; 29/592.1; 361/679.01

(57) ABSTRACT

A substrate material having a mechanical filtering characteristic, the substrate material having at least one support region for supporting the substrate material. In addition, the substrate material includes a sensor region having sensor terminal contacts. Furthermore, the substrate material includes a separating region, which is coupled to the at least one support region and the sensor region and is situated between the at least one support region and the sensor region. In this context, the substrate material in the separating region has a structure different from the substrate material in the support region and/or in the sensor region, in order to form a mechanical filtering characteristic.

### FIELD OF THE INVENTION

The present invention relates to a substrate material, a sensor unit, as well as a method for producing a substrate material.

### BACKGROUND INFORMATION

Nowadays, various sensors for detecting vehicle motions, such as an acceleration or a rate of rotation, are used in control units of vehicles. The sensors are placed on a support, for example, a board, and joined to the vehicle by a mostly rigid, mechanical coupling, e.g., a screw connection of the board to a housing of the control unit. Analog measured variables in the sensor are digitally converted and made available to an evaluation unit of the control unit. Several measured sensor variables may be logically combined by the evaluation unit of the control unit, in order to implement system functions.

In a vehicle, interference signals are generated by environmental effects such as vibration. One advantage of the control unit is that it may be integrated into the vehicle in a compact manner; however, in addition to a desired, useful signal, an interference signal superimposed on the useful signal may reach a sensor element. Consequently, the interference signal may possibly result in degradation of the functioning of the sensor element. The interference signal may be transmitted through a mechanical coupling between the vehicle and the sensor element, via a sensor support. Current approaches for diminishing interference signals make use of mechanically damping materials. For example, a foamed-plastic damping mat between the vehicle and the sensor support is often used for reducing the effect of the interference signal on the useful signal via the mechanical coupling. In addition, the mechanical coupling may be changed by positioning a damping material between the sensor and the support.

A combination of a mechanical filter and a control system, which is provided for a robot or a manipulator, is discussed in the published application US 2003/0132726 Al.

### SUMMARY OF THE INVENTION

Against this background, a substrate material, furthermore, a sensor element, as well as a method of producing according to the description herein, are put forward by the exemplary embodiments and/or exemplary methods of the present invention. Advantageous refinements are derived from the respective descriptions herein and the following description.

The exemplary embodiments and/or exemplary methods of the present invention provide a substrate material having a mechanical filtering characteristic, the substrate material having the following regions:
at least one support region for supporting the substrate material;
a sensor region having sensor terminal contacts; and
a separating region, which is coupled to the at least one support region and the sensor region and is situated between the at least one support region and the sensor region; the substrate material in the separating region having a structure different from the substrate material in the support region and/or in the sensor region, in order to form a mechanical filtering characteristic.

The exemplary embodiments and/or exemplary methods of the present invention further provide a sensor unit, which has the following features:
a substrate material according to one of the preceding claims; and
a sensor element, which is situated on the substrate material in the sensor region, and which is configured to detect mechanical motions or vibrations and to generate a sensor signal characteristic of the mechanical motions or vibrations.

The exemplary embodiments and/or exemplary methods of the present invention further provide a method for producing a substrate material having a mechanical filtering characteristic, the method having the following steps:
providing a substrate board, the substrate board including a support region for supporting the substrate board; and
introducing a structure into a separating region between the support region and a sensor region of the substrate board; after the introducing step, the separating region having a structure different from the support region and/or the sensor region, in order to obtain a mechanical filtering characteristic.

The exemplary embodiments and/or exemplary methods of the present invention are intended to promote the objective of diminishing (attenuating) or preventing an interference signal arriving at a sensor element. This is achieved in that, before it can reach the sensor element, the interference signal passes through a mechanical filter. The mechanical filter has the task of attenuating an interference signal in a particular frequency range, which is critical for the correct functioning of the sensor element, while a useful signal is supposed to reach the sensor element as unhindered as possible.

A direct, advantageous effect of the exemplary embodiments and/or exemplary methods of the present invention is that the mechanical filter may allow an improved ratio of useful signal power to interference signal power to be achieved. Therefore, the evaluation unit of the control unit may be provided with a measuring signal having higher accuracy. As an alternative, when uniform measurement accuracy is desired, fewer demands may be placed on the sensor element, which may lead to the use of a less expensive sensor element.

An additional important advantage is that interference signals having frequencies, in which a sensor is particularly sensitive, are avoided during the recording of measured values. Sensitivity of the sensor means that the sensor must only be excited at a low mechanical signal power and a particular frequency, in order to generate interference signals in a useful band. The interference signals having new frequencies are generated due to nonlinear effects in the sensor element in the event of excitation by vibrations externally applied. This may increase an overall interference power and decrease the ratio of useful signal power to interference signal power. The useful signal, which is output by the sensor to the evaluation unit and is superposed by an interference signal, may then be distorted or even unusable.

The exemplary embodiments and/or exemplary methods of the present invention are believed to offer the advantage that an effect on a mechanical transfer function may even be achieved without the aid of additional components, such as foamed plastic or damping materials. Thus, for example, a mechanical filtering effect may be achieved by suitable selection of recesses in a separating region around the sensor or the sensor region in the substrate material. This means for attaining the objective offers an approach optimized with regard to cost, in particular, for areas of application in which high demands are placed for a specific mechanical transfer function at a low cost.

In addition, ageing-related problems during the use of additional material, such as foamed plastic or damping materials, are prevented. Since these utilized materials often change their mechanical properties during an operating time of the sensor, the use of such materials involves a risk of unforeseeable system effects. Thanks to an implementation of the mechanical filter in a substrate material, for example, a circuit board, in the form of the separating region, additional materials having ageing characteristics may be dispensed with.

The exemplary embodiments and/or exemplary methods of the present invention are based on the realization that a mechanical filter may be produced in view of the shape, type of material and structure of a region of a substrate material. This region of the substrate material, which may be referred to as a separating region, is distinguished by a change in the substrate material, such as with regard to the shape, the type of material and/or the structure. In this context, the shape may include a rectangular shape, circular shape or a mixed shape made up of a rectangular and circular shape. In particular, in the case of the type of material, the separating region may even be made of a material identical to the substrate material in the support region and/or in the sensor region, in order to introduce a structure of the separating region in a simple production step. The structure may be formed by a recess or one or more openings in the separating region. In this context, the separating region is situated between a support region and a sensor region, in order to produce a mechanical coupling or, in the best case, a mechanical decoupling with regard to vibrations of the support region and the sensor region. One measure of the mechanical coupling is a transfer function, which represents a response to an excitation of a mechanical system in a predetermined frequency range. In this context, the transfer function (as viewed from the sensor region) may be a function of mechanical characteristics, such as the shape, the material and/or the structure of the separating region. These mechanical characteristics may be advantageously used for adapting a transfer function to a sensitivity characteristic of a sensor to be mounted in the sensor region. In this manner, a protective function against interference signals may be implemented for a sensor to be integrated in the sensor region of the substrate material. A protective function is then necessary, when mechanical vibrations could damage the sensor or result in erroneous sensor signals. In this context, the mechanical filter aids in filtering out frequencies that destroy the sensor or distort the measuring signal.

According to one specific embodiment of the present invention, the substrate material in the separating region may have a lesser or a greater thickness than the substrate material in the support region and/or in the sensor region. Different material thicknesses may result in different resonance behavior of the entire substrate material. A transfer function may be derived as a function of the configuration of the different material thicknesses. In this manner, the transfer function may be adapted, for example, to a mechanical environment or to a sensitivity characteristic of a sensor to be situated in the sensor region of the substrate material, so that such a sensor may supply sensor signals, which are scarcely or not at all deteriorated by interference signals.

According to another specific embodiment of the present invention, the substrate material may have at least one opening in the separating region. The at least one opening changes the structure of the material in the separating region and may be easily produced, for example, using an appropriate processing method. Using the at least one opening, and from the resulting structure of the material in the separating region, a transfer function may be adapted to a sensitivity characteristic of a sensor mounted in the sensor region.

In a further specific embodiment of the present invention, the separating region may include partial regions, which have different thicknesses of the substrate material. Patterning the separating region to have different thicknesses of the substrate material of a partial region allows frequency-specific damping of an interference signal or frequency-specific passage of a useful signal within a partial region. In this context, position-dependent attenuation of the interference signal may be possible as a function of a position of the partial region in the separating region.

In a further specific embodiment of the present invention, the separating region may surround the sensor region except for at least one transition region, the separating region being able to be split by the transition region. The transition region may be made of the same material as the material of the separating region, but only with an appropriately modified structure, in order not to exert any influence on the transfer function. In this context, the separating region may be separated or interrupted by transition regions as often as needed. Using a predetermined number and/or a predetermined configuration of transition regions, the transfer function may be flexibly adapted for the sensor region. Nevertheless, a certain rigidity of the sensor region may be ensured at the same time, since, in this region, the sensor may be mounted and electrically contacted on the substrate material.

According to a specific embodiment of the present invention, the separating region may have a rectangular shape and/or completely surround the sensor region. In one development of the separating region, which completely surrounds the sensor region, a mechanical coupling of the sensor region to the substrate material may be optimized in such a manner, that vibrations must always pass through the separating region in order to reach the sensor region. In addition, a separating region patterned in such a manner may be produced in a highly simple manner and therefore reduces the cost of a corresponding substrate material.

According to another specific embodiment of the present invention, the separating region may have a circular shape and completely surround the sensor region. The circular shape may be advantageous, since in the case of such a shape, no corners and/or edges occur at which mechanical vibrations may be reflected. In the realization of a desired transfer function, the use of a circular shape may simplify its calculation. In this context, the transfer function in the circular sensor region may be optimized in such a manner, that a maximum attenuation of an interference signal is achieved.

In one further specific embodiment of the present invention, the separating region may have a least one groove as a structure, and/or the separating region may completely surround the sensor region. The groove introduced into the separating region may constitute a region for blocking off, from the sensor region, an interference signal originally coming from the substrate material in the support region. In this context, location-specific attenuation of the interference signal may be implemented using a position of the groove.

According to one specific embodiment of the present invention, the separating region may be configured to generate a mechanical spring action between the support region and the sensor region. The transfer function for the sensor region may be set with the aid of the mechanical spring action. The mechanical spring action may be produced, for example, by a mechanical spring made of a material different from the substrate material or, for example, by a meander-shaped structure introduced into the substrate material.

In one further specific embodiment of the present invention, the substrate material may be a circuit board and may have electric conductor tracks. The formation of the substrate material, the separating region and the sensor region out of an identical circuit-board material may be advantageous in one respect, in that electrical components may be mounted on the circuit-board material, and/or a circuit and/or integrated circuits may be situated on the circuit-board material. In addition, the separating region may be structurally formed in a single working step, when the material of the separating region is intended to be identical to the material of the substrate material. Furthermore, the separating region may possibly be formed by advantageously routing conductor tracks on the circuit board.

The exemplary embodiments and/or exemplary methods of the present invention are explained in greater detail by way of example, with reference to the attached drawing.

### BRIEF DESCRIPTION OF THE DRAWINGS

FIG. 1 shows a top view of a detail of a substrate material having a mechanical filtering characteristic, according to an exemplary embodiment of the present invention.

FIG. 2 shows a top view of a detail of a substrate material having a different mechanical filtering characteristic, according to an exemplary embodiment.

FIG. 3 shows a signal transmission chain according to an exemplary embodiment of the present invention.

FIG. 4 shows a graphical representation of different transfer functions according to an exemplary embodiment of the present invention.

FIG. 5 shows a flow chart of a method for producing a substrate material having a mechanical filtering characteristic, according to an exemplary embodiment of the present invention.

### DETAILED DESCRIPTION

In the figures, identical or similar elements may be provided with the same or similar reference numerals and are described only once. In addition, the figures of the drawing, their description and the claims contain numerous features in combination. In this context, it is clear to one skilled in the art that these features may also be considered individually or may be combined to form further combinations not explicitly described here.

In the following description, the exemplary embodiments and/or exemplary methods of the present invention may also be explained using different sizes and dimensions, although the present invention is not to be understood as being limited to these sizes and dimensions. Furthermore, method steps of the present invention may be executed repeatedly, as well as in an order other than that described. If an exemplary embodiment includes an “and/or” conjunction between a first feature/step and a second feature/step, then this can be read to mean that according to a specific embodiment, the exemplary embodiment has both the first feature/the first step and the second feature/the second step, and that according to a further specific embodiment, the exemplary embodiment either has only the first feature/step or only the second feature/step.

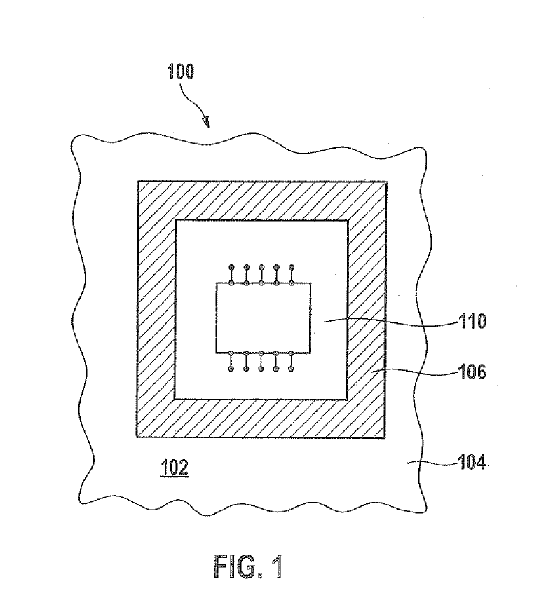

FIG. 1 shows a top view of a detail of a substrate material 100 having a mechanical filtering characteristic, according to an exemplary embodiment of the present invention. In this context, substrate material 102 is subdivided into a support region 104 corresponding to the detail, a separating region 106 and a rectangular sensor region 110. A sensor 110 including terminal contacts is situated on the sensor region. Separating region 106 completely surrounds rectangular sensor region 110; separating region 106 producing a mechanical coupling between support region 104 and sensor region 110. Sensor 110 may be contacted via electrical lines, which are not shown and are routed from support region 104 to sensor region 110 via separating region 106.

The substrate material 100, which is illustrated in FIG. 1 and has a mechanical filtering characteristic, may be understood as a mechanical filter 106 that is integrated in a circuit board 102 used as a substrate material 102. Mechanical filter 106 may be produced, for example, using recesses in separating region 106 on circuit board 102. By changing a mechanical coupling of sensor 110 to substrate material 102, a filtering effect may be achieved that may have a direct influence on an interference signal. To that end, it is necessary to decouple sensor 110 as much as possible from substrate material 102 in support region 104. This may be achieved by recesses in separating region 106 of substrate material 102.

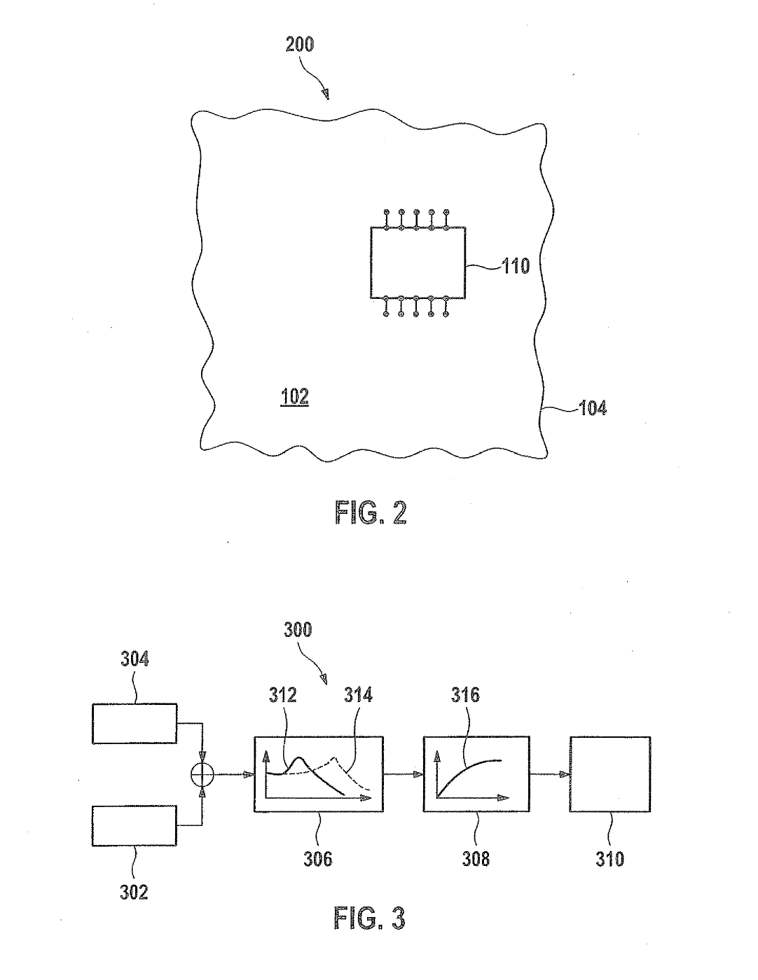

In comparison, FIG. 2 shows a top view of a detail of a substrate material 200 not having a mechanical filtering characteristic. In this context, a material of sensor region 110 is identical to a material of substrate material 102110, and patterning in separating region 106 has been omitted. In this case, a sensor 110 situated on sensor region 110 is directly coupled to circuit board 102 and the support region without a mechanical filter. In this manner, interference signals may not be advantageously kept away from the sensor.

FIG. 3 shows a signal transmission chain 300 according to an exemplary embodiment of the present invention. In this context, a useful signal 304 superimposed with an interference signal 302 is fed to a sensor 308 via a transmission channel 306, the sensor transmitting a corresponding electric output signal to a data processing unit, for example, a microcontroller of an electric control unit, 310. In general, useful signal 304 is superimposed with interference signals 302, for example, from vibrations, the interference signals interfering with useful signal 304. In this case, the transmission channel is described with the aid of different transfer functions, which form the response characteristic of this transmission channel 306.

If, by way of the above-described separating region, a mechanical filter is integrated in transmission channel 306, which represents the mechanical coupling between the vehicle and sensor 308, then interference signal 302 may be filtered out of useful signal 304 with the aid of a transfer function modified by the mechanical filter. In FIG. 3, the comparison between a transfer function with the mechanical filter 312 and a transfer function without the mechanical filter 314 is shown by way of example. A deviation between the two transfer functions 312, 314 is generated by the mechanical filter of the separating region, which was described in detail in one of the preceding descriptions. Subsequently, a useful signal processed by the mechanical filter is supplied to sensor 308. Sensor 308 detects an incoming signal, for example, a mechanical signal, and transforms the incoming signal into an, e.g., electrical, output signal to be output, with the aid of a response function 316 specific to sensor 308. The output signal of sensor 308 is used as an input signal for the microcontroller of electric control unit 310, the input signal being processed further in control unit 310.

In summary, it should be noted that in FIG. 3, a signal transmission from a vehicle to a sensor 308 is illustrated. Useful and interference signals 304, 302 are superposed in the vehicle and are transmitted to sensor 308 as an overall signal by a mechanical transfer function 312, 314. Nonlinearities present in sensor 308 have an effect on an output signal of sensor 308, which is used, in turn, as an input signal for an evaluation unit 310.

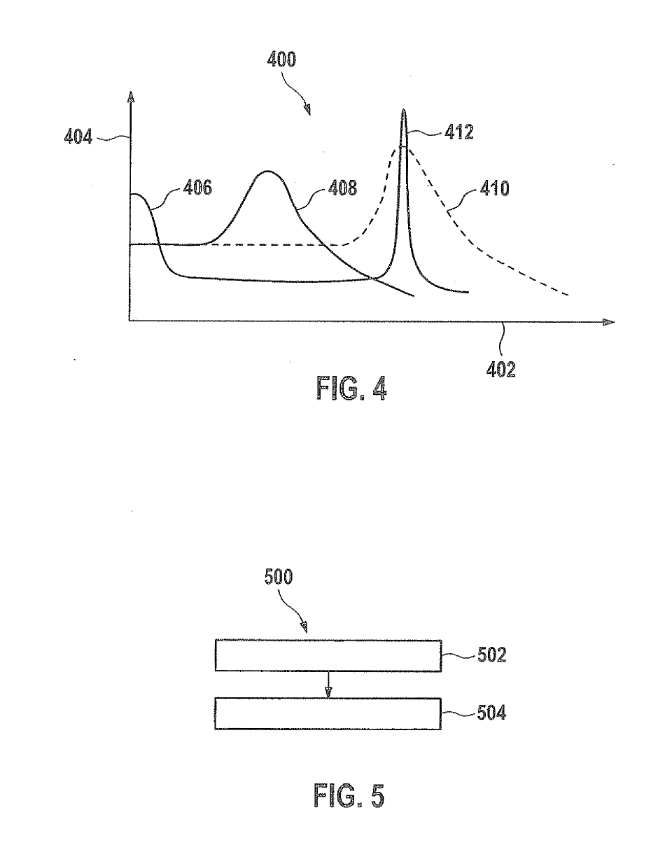

FIG. 4 shows a graphical representation 400 of different transfer functions according to an exemplary embodiment of the present invention. In this context, amplitudes of different transfer functions are plotted on a vertical amplitude response axis 404, along the horizontal frequency axis 402. The transfer functions include a transfer function 406 of the sensor, a transfer function 408 with a mechanical filter, and a transfer function 410 without a mechanical filter. Transfer function 406 of the sensor shows two distinct maxima, a first maximum occurring in a lower frequency range, and a second maximum occurring in an upper frequency range. Transfer function 408 of the substrate material having a mechanical filter and transfer function 410 of the substrate material not having a mechanical filter each show one maximum in the amplitude response, the maximum of transfer function 410 of the substrate material not having a mechanical filter being superposed with the second maximum in the upper frequency range. The maximum of transfer function 408 with the mechanical filter is shown displaced in a medium frequency range between the upper and lower. A special situation, particularly in the upper frequency range, is apparent from graphical representation 400. In this context, an interference signal in the upper frequency range, which is indicated as a sensitive frequency range 412 of the sensor, leads to an excitation of the sensor. In a resonant frequency range 412, which corresponds to the upper frequency range, excitation of the sensor may result in deterioration of, all the way up to unusability of, the useful signal. In the extreme case, it could cause damage to the sensor. Therefore, using mechanical filter, transfer function 410 of the substrate material is changed, and a new transfer function 408 is produced, in which an interference signal occurring in sensitive frequency range 412 of the sensor is attenuated and functional impairment of the sensor is prevented.

Thus, in summary, transfer functions (TF) in the system, e.g., in a vehicle, are shown in FIG. 4. By introducing a mechanical filter, this changes the transfer function of the substrate material from a support region to a sensor region. The sensor itself may remain mounted on a substrate material, in order to facilitate assembly, for example, in the case of automatic assembly. In addition, the sensor may be joined to the vehicle with the aid of other materials. A mechanical coupling is produced in a precise manner, using specific transition elements between the substrate material and the sensor. The new coupling structure between substrate and sensor advantageously produces a specific mechanical transfer function 408 having a filtering effect.

An effect of the mechanical filter may be clarified with the aid of FIG. 4. The effect of the mechanical filter or its filtering action may be established by plotting mechanical transfer function 408, 410. In this connection, a first control unit not having a mechanical filter is excited on a vibration table. An exciting vibration is measured by a reference sensor. A reference sensor additionally mounted to the sensor element measures the vibrations occurring at the sensor. After running through a frequency range, an attenuation or an amplification, starting out from a control unit housing, through the substrate material, up to the sensor, may be determined and manifest itself as a mechanical transfer function 408, 410. Subsequently, the same control unit is changed using the above-described measures. A second control unit provided with a mechanical filter is measured on the same measuring set-up. A filtering function may be calculated from the two mechanical transfer functions 408, 410 present.

FIG. 5 shows a flow chart of a method 500 for producing a substrate material having a mechanical filtering characteristic, according to an exemplary embodiment of the present invention. In this context, method 500 may be used for producing an exemplary embodiment shown in FIG. 1. In a providing step 502, a substrate board is provided, the substrate board including a support region for supporting the substrate board. In one exemplary embodiment, the substrate board may constitute a circuit board. In addition, in an introducing step 504, a structure of a separating region is introduced between the support region and a sensor region of the substrate board, the separating region having a structure different from the support region and the sensor region, in order to obtain a mechanical filtering characteristic. The introduction of a structure onto the separating region may constitute a partial, local removal of the substrate material, for example, in the form of a groove, or a complete, local removal of the substrate material, for example, in the form of an opening or a meander-shaped structure as a spring element.

1-10. (canceled)

11. A substrate material arrangement, comprising:
a substrate material having a mechanical filtering characteristic;
wherein the substrate material has the following:
at least one support region for supporting the substrate material,
a sensor region having sensor terminal contacts, and
a separating region, which is coupled to the at least one support region and the sensor region and is situated between the at least one support region and the sensor region, and
wherein the substrate material in the separating region has a structure different from the substrate material in at least one of the support region and the sensor region, so as to form the mechanical filtering characteristic.

12. The substrate material of claim 11, wherein the substrate material in the separating region has a lesser or a greater thickness than the substrate material in at least one of the support region and the sensor region.

13. The substrate material of claim 11, wherein the substrate material in the separating region has at least one opening.

14. The substrate material of claim 11, wherein the separating region includes partial regions having different thicknesses of the substrate material.

15. The substrate material of claim 11, wherein the separating region surrounds the sensor region except for at least one transition region, the separating region being split by the transition region.

16. The substrate material of claim 11, wherein the separating region has a rectangular shape and/or completely surrounds the sensor region.

17. The substrate material of claim 11, wherein at least one of the following is satisfied: (i) the separating region has at least one groove as a structure, and (ii) the separating region completely surrounds the sensor region.

18. The substrate material of claim 11, wherein the separating region is configured to generate a mechanical spring action between the support region and the sensor region.

19. A sensor unit, comprising:
a substrate material arrangement, comprising:
a substrate material having a mechanical filtering characteristic;
wherein the substrate material has the following:
at least one support region for supporting the substrate material,
a sensor region having sensor terminal contacts, and
a separating region, which is coupled to the at least one support region and the sensor region and is situated between the at least one support region and the sensor region, and
wherein the substrate material in the separating region has a structure different from the substrate material in at least one of the support region and the sensor region, so as to form the mechanical filtering characteristic; and
a sensor element situated on the substrate material in the sensor region and configured to detect mechanical motions or vibrations and to generate a sensor signal characteristic of the mechanical motions or vibrations.

20. A method for producing a substrate material having a mechanical filtering characteristic, the method comprising:
providing a substrate board, which includes a support region for supporting the substrate board; and
introducing a structure of a separating region between the support region and a sensor region of the substrate board, the separating region having a structure different from that of the support region and that of the sensor region, so as to obtain the mechanical filtering characteristic.
